(19) United States
(12) Patent Application Publication
(10) Pub. No.: US 2025/0138060 A1
(43) Pub. Date: May 1, 2025

(54) LINEAR GAIN TRIM FOR LOW TEMPERATURE COEFFICIENT INTEGRATED CURRENT SENSOR

(71) Applicant: Analog Devices, Inc., Wilmington, MA (US)

(72) Inventors: Eric A. Sagen, Colorado Springs, CO (US); Gregory J. Manlove, Colorado Springs, CO (US)

(21) Appl. No.: 18/498,731

(22) Filed: Oct. 31, 2023

(51) Int. Cl. G01R 19/25

(52) U.S. Cl. CPC G01R 19/25

(57) ABSTRACT

Described are techniques to provide a gain trim term in the numerator for a current sensor control loop. In this manner, a linear gain trim relationship is created with respect to the trim code. This linear relationship reduces the dynamic range needed for the DAC, which allows the use of lower resolution DACs to smoothly adjust the gain while maintaining stability and accuracy.

### FIELD OF THE DISCLOSURE

This document pertains generally, but not by way of limitation, to an electrical current sensor, and more particularly, but not by way of limitation, to a laminate-based “zero” temperature coefficient current sensor.

### BACKGROUND

Sensing large currents on a printed circuit board (PCB), such as can be found at the 12V DC input to a server or network switch, can require using a sense element that is capable of passing large currents safely and with minimal power loss. For sensing input currents in excess of 100 amperes, a sense element resistance on the order of 150 μΩ or less may be needed. Such a sense element can come in the form of a discrete sense resistor, such as can be soldered to the PCB, or even a resistor formed by the resistance of a PCB trace itself. The voltage developed across the sense resistance can be measured by various means including using an analog-to-digital converter (ADC) in the system, which can be further conditioned or signal-processed to produce a value indicating the sensed current (e.g., in Amperes) representing the current through the sense element.

Discrete sense resistors having low temperature coefficients tend to be made from exotic materials, such as iron-chrome or manganese-copper alloys. These exotic materials can achieve a low temperature coefficient of resistance (TCR) but can be expensive. Accurately sensing the voltage across such a sense resistor element can also be difficult, given the large current (resulting in ohmic “IR” voltage drops across the PCB) and a small voltage drop across the sense resistor being used as the current sense element, as is needed to maintain a reasonable power dissipation in the sense resistor. Some Kelvin-sense resistors are available, such as can include sense points integrated into the sense resistor, but these tend to be even more expensive.

Another way of sensing large currents is by using a section of a copper PCB trace itself as the current sense element. This has the advantage that the PCB trace already exists on the PCB and no additional voltage drops (such as due to a discrete sense element) need to be introduced. However, copper has a large TCR (3900 ppm/° C.). Thus, as the PCB changes temperature, either due to ambient temperature changes or due to the power dissipation from the IR drop across the copper trace, the absolute resistance of the sense element will change. While this effect can be compensated, such as by using a temperature sensor near the sense element and some analog or digital signal conditioning in the measurement circuitry, such temperature compensation involves additional complexity.

Furthermore, the accuracy of a discrete current sense resistor, or the thickness and width of the PCB trace, may not be controlled well enough to achieve the desired final system accuracy. Trim techniques can be applied to the final PCB assembly, but this adds test cost and complexity to the PCB manufacturing process, assuming that the current can be externally measured or applied accurately enough to achieve the desired trim target.

### SUMMARY OF THE DISCLOSURE

This disclosure describes various techniques to provide a gain trim term in the numerator for a current sensor control loop. In this manner, a linear gain trim relationship is created with respect to the trim code. This linear relationship reduces the dynamic range needed for the DAC, which allows the use of lower resolution DACs to smoothly adjust the gain while maintaining stability and accuracy.

In some aspects, this disclosure is directed to a system current sensor module for accurately performing at least one of a current sensing or measurement of a system current, the system current sensor module comprising: an input node, an output node, and a system current monitor node; an output transistor coupled between the input node and the output node; a first resistive element coupled between the input node and the system current monitor node; a second resistive element coupled between the input node and the output transistor; and an amplifier, including a first amplifier input coupled to the second resistive element, a second amplifier input coupled to an output node of a trim circuit, and an amplifier output coupled to a control node of the output transistor.

In some aspects, this disclosure is directed to a method of sensing or measuring a system current comprising: in response to a system current flowing between an input node and a system current monitor node via a first resistive element, shunting an output current via a second resistive element; adjusting, using a trim circuit coupled across and in parallel with the first resistive element, a gain between the input node and the system current monitor node; and controlling, using an amplifier that is configured in a closed feedback loop, the output current in a manner that tends to reduce or minimize a voltage difference across first and second inputs of the amplifier.

In some aspects, this disclosure is directed to a system current sensor module for accurately performing at least one of a current sensing or measurement of a system current, the system current sensor module comprising: an input node, an output node, and a system current monitor node; an output transistor coupled between the input node and the output node; a first resistive element coupled between the input node and the system current monitor node; a second resistive element coupled between the input node and the output transistor; means for adjusting a gain between the input node and the system current monitor node; and means for controlling the output monitor current in a manner that tends to reduce or minimize a voltage difference across first and second inputs of an amplifier.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 shows an example of a system current sensor module architecture.

FIG. 2 shows an example of a system current sensor module 200 architecture that can implement various techniques of this disclosure.

FIG. 3 shows an example of a system current sensor module 300 architecture that can implement various techniques of this disclosure.

FIG. 4 is a flow chart of an example of a method of sensing or measuring a system current.

### DETAILED DESCRIPTION

Traditional current sensor control loops utilize a gain trim term in the denominator. The present inventors have recognized that the gain trim term in the denominator creates a non-linear relationship with respect to the trim code. This non-linear relationship requires high resolution digital-to-analog converters (DACs) to finely tune the gain adjustment. High resolution DACs increase cost and power consumption.

The present inventors have recognized that by moving the gain trim term from the denominator to the numerator, a linear gain trim relationship is created with respect to the trim code. This linear relationship reduces the dynamic range needed for the DAC, which allows the use of lower resolution DACs to smoothly adjust the gain while maintaining stability and accuracy.

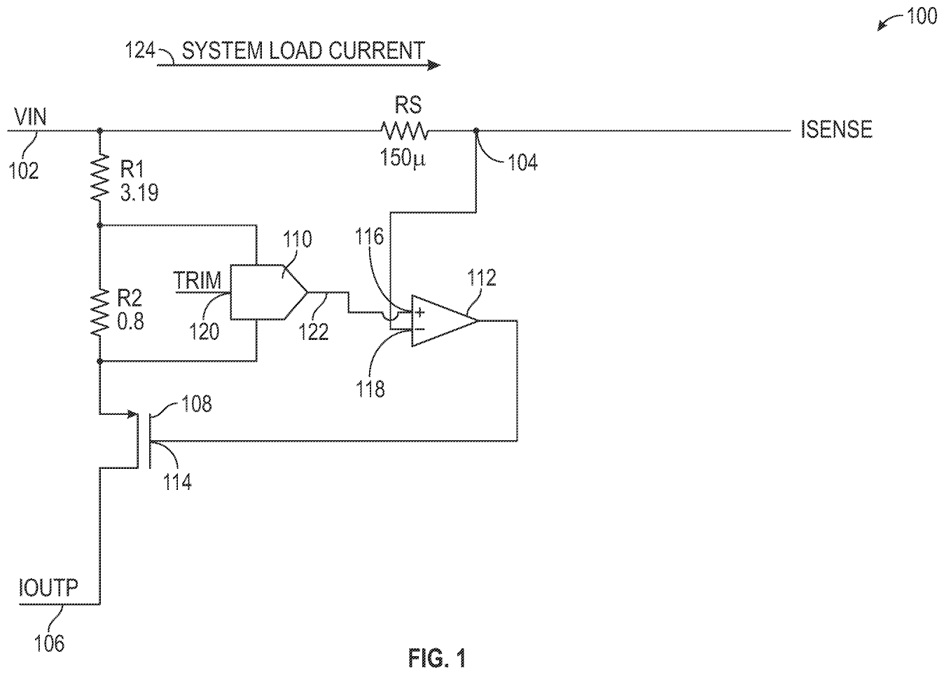

FIG. 1 shows an example of a system current sensor module 100 architecture. The system current sensor module 100 includes an input node 102 to receive an input voltage VIN, a system current monitor node 104 at which an output monitor current ISENSE can be monitored, and an output node 106 at which an output monitor current IOUTP is generated.

A current “sense” resistive element RS, e.g., resistor, is between the input node 102 and the system current monitor node 104, such as having a resistance value of about 150 μΩ, can serve as the primary current sense element. The large “system load current” 124 from the system flows through this current sense resistor RS.

Gain setting resistive elements R1 (e.g., 3.19Ω) and R2 (e.g., 0.8Ω), e.g., resistors, are connected in series between the input node 102 and the output transistor 108. As seen in FIG. 1, a trim circuit 110 is coupled in parallel with the resistive element R2. The trim circuit 110 is configured to receive a trim code via a trim code input 120 and, in response modify a voltage dependent on the VIN voltage at node 104, gain setting resistive elements R1 and R2 and the sensor output current flow through transistor 108.

The output 122 of the trim circuit 110 is coupled to a non-inverting (a first input 116) of the amplifier 112. The system current monitor node 104 is coupled to the inverting input (second input 118) of the amplifier 112. The output of the amplifier 112 is coupled to a control node 114 of the output transistor 108, e.g., a field-effect transistor (FET). The amplifier 112 is configured in a closed feedback loop to control the output current IOUTP in a manner that tends to reduce or minimize a voltage difference across the first input 116 and the second input 118 of the amplifier 112. In this manner, the system current sensor module 100 can modify the attenuation of the feedback to trim in the gain.

The output monitor current IOUTP of the system current sensor module 100 is given by Equation 1:

$$I OUT P = ( IIN * RS ) / ( R 1 + AV * R 2 ) \qquad Equation 1$$

where IOUTP is the output monitor current, IIN is the system load current, RS is the resistance of the resistive element RS, R1 is the resistance of the resistive element R1, AV is the trim gain term, and R2 is the resistance of the resistive element R2.

As seen in Equation 1, the gain term AV is in the denominator, which produces a non-linear relationship between the error term and the gain adjustment. The non-linear relationship complicates the trim algorithm because small changes in the error have large impacts on the adjust gain when the error is small, but smaller impacts when the error is large. This can require very high resolution DACs to smoothly adjust the gain.

The present inventors have recognized the desirability of having the trim gain term in the numerator of the equation, which results in a linear relationship that can reduce requirements of the minimum trim resolution.

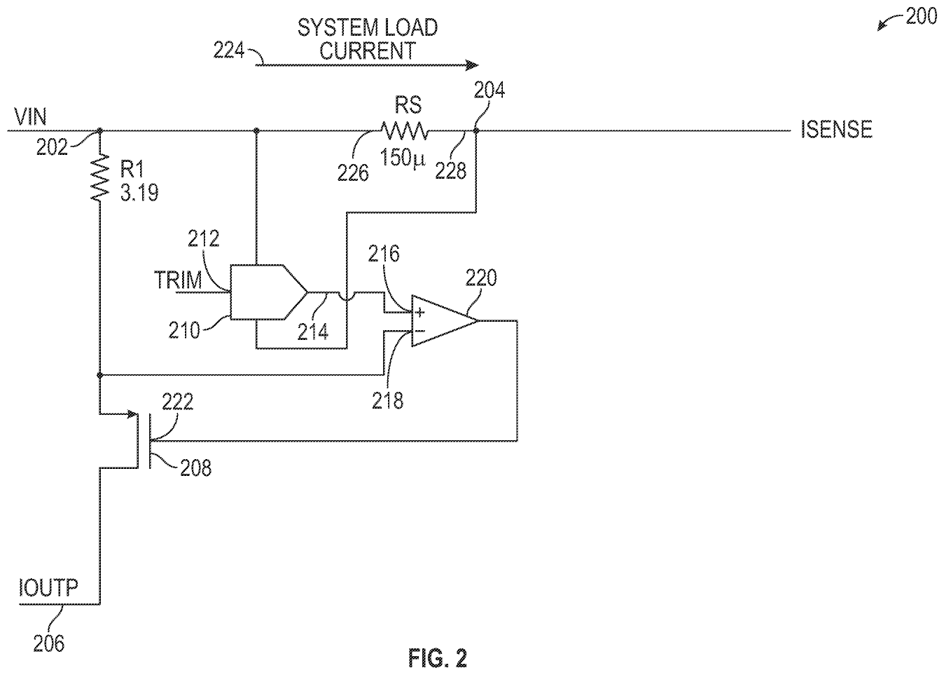

FIG. 2 shows an example of a system current sensor module 200 architecture that can implement various techniques of this disclosure. The system current sensor module 200 includes an input node 202 to receive an input voltage VIN, a system current monitor node 204 at which an output monitor current ISENSE can be monitored, and an output node 206 at which an output monitor current IOUTP is generated.

A current “sense” resistive element RS is between the input node 202 and the system current monitor node 204, such as having a resistance value of about 150 μΩ, can serve as the primary current sense element. The large “system load current” 224 from the system flows through this current sense resistor RS.

A gain setting resistive element R1 (e.g., 3.19Ω) is connected in series between the input node 202 and the output transistor 208. In contrast to the system current sensor module 100 in FIG. 1, a trim circuit 210 is coupled in parallel with the resistive element RS. The resistive element RS has a first node 226 and a second node 228, and the trim circuit 210 is coupled with the first node 226 and the second node 228.

The trim circuit 210 is configured to receive a trim code (“TRIM”) via a trim code input 212 and, in response, modify a voltage between the input node 202 and the system current monitor node 204. For example, the trim circuit 210 can couple a resistance corresponding to the trim code in parallel with the resistive element RS to adjust the gain between a system load current 224 and an output monitor current IOUTP.

In addition, using the techniques of this disclosure, the resistive element R2 of FIG. 1 has been eliminated, which simplifies the resistor network. By using these techniques, the gain term is now in the numerator of the equation, which results in a linear relationship that can reduce or minimize the required trim resolution.

The output monitor current IOUTP of the system current sensor module 200 is given by Equation 2:

$$I OUT P = ( IIN * RS * AV ) / R 1 \qquad Equation 2$$

where IOUTP is the output monitor current, IIN is the system load current, RS is the resistance of the resistive element RS, R1 is the resistance of the resistive element R1, and AV is the trim gain term.

The output 214 of the trim circuit 210 is coupled to a non-inverting (a first input) of the amplifier 220. The source of the transistor 208 and the resistor R1 node 211 is coupled to an inverting input (second input 218) of the amplifier 220. The output of the amplifier 220 is coupled to a control node 222 of the output transistor 208, e.g., a FET. The amplifier 220 is configured in a closed feedback loop to control the output monitor current IOUTP in a manner that tends to reduce or minimize a voltage difference across the first input 216 and the second input 218 of the amplifier 220.

It can be helpful to keep the two resistors (e.g., the resistive element RS and the resistive element R1) at the same temperature, such as to help maintain a stable gain over temperature and to help reduce errors due to aging. Since the largest power dissipation will occur in the he resistive element RS (which can have the full, large, system current flowing through it), the resistive element R1 can be constructed so as to be thermally coupled to the resistive element RS, such that both of these resistive elements RS, R1 are at about the same temperature and experience the same temperature variations. This can include forming a “thermal cage” to help keep the resistive element RS and the resistive element R1 at the same temperature. As such, in some examples, the resistive element RS and the resistive element R1 are thermally coupled to keep a temperature of the second resistive element at or near a temperature of the first resistive element when a system load current is flowing through and heating the first resistive element. Additional information can be found in commonly assigned U.S. Pat. No. 11,378,595 titled “Low temperature coefficient current sensor” to Michael D. Petersen et al., the entire contents of which being incorporated herein by reference.

In some examples, the resistive element RS and the resistive element R1 include the same material. For example, both the resistive element RS and the resistive element R1 can be copper.

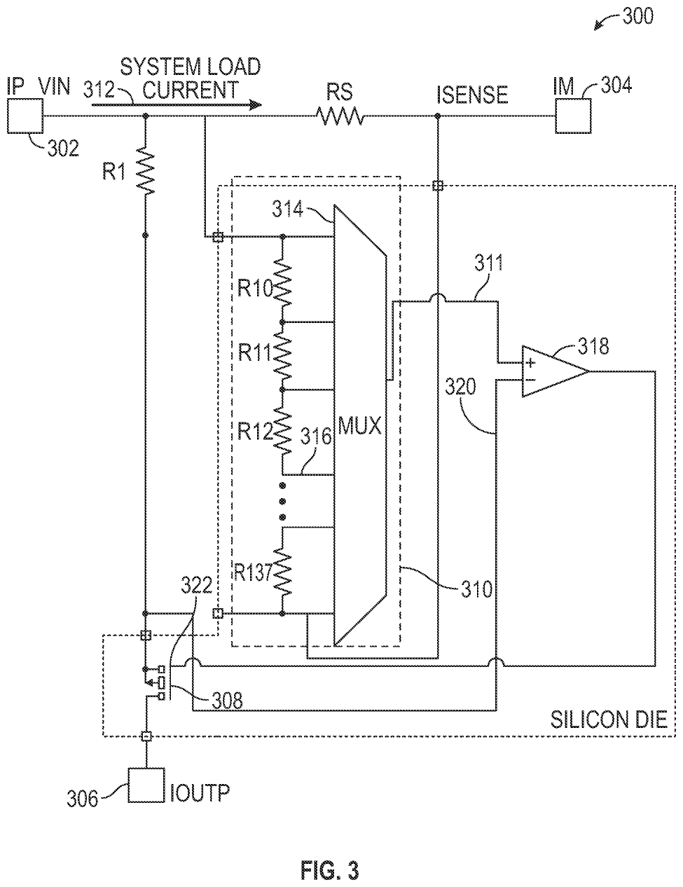

In some examples, the trim circuit 210 can include a digital-to-analog converter. An example of such an implementation is shown and described below with respect to FIG. 3.

FIG. 3 shows an example of a system current sensor module 300 architecture that can implement various techniques of this disclosure. The system current sensor module 300 includes an input node 302 to receive an input voltage VIN, a system current monitor node 304 at which an output monitor current ISENSE can be monitored, and an output node 306 at which an output monitor current IOUTP is generated.

A current “sense” resistive element RS is between the input node 302 and the system current monitor node 304, such as having a resistance value of about 150 μΩ, can serve as the primary current sense element. The large “system load current” 312 from the system flows through this current sense resistor RS.

Like in FIG. 2, a gain setting resistive element R1 (e.g., 3.19Ω) is connected in series between the input node 302 and the output transistor 308, and a trim circuit 310 is coupled in parallel with the resistive element RS. The trim circuit 310 can be a digital-to-analog converter. For example, the trim circuit 310 can be a voltage digital-to-analog converter. In the example shown in FIG. 3, the voltage digital-to-analog converter can be a resistor divider digital-to-analog converter that includes an interpolation string 316 having a series combination of resistive elements R10, R11, R12, . . . , R137 and a multiplexer circuit 314. The interpolation string 316 is a variable resistance.

The interpolation string 316 includes tap points between or across the resistive elements R10, R11, R12, . . . , R137 for allowing such tap points to be selectively multiplexed by the multiplexer circuit 314 to the non-inverting input) 325 of the amplifier 318. This allows the trim circuit 310 and, in particular, the multiplexer circuit 314, to receive a trim code and, in response, modify a voltage between the input node 302 and the system current monitor node 304. For example, the trim circuit 310 can couple a selected resistive element R10, R11, R12, . . . , R137 corresponding to the trim code in parallel with the resistive element RS to adjust the gain between a system load current 324 and the output monitor current IOUTP.

In this manner, the trim circuit 310, such as including a digital-to-analog converter as in FIG. 3, can modify a voltage between the input node and the system current monitor node by modifying the voltage between the input node and the system current monitor node includes modifying a resistance of a variable resistance, e.g., modifying the resistance of the interpolation string 316, coupled in parallel with the resistive element RS. For example, the resistance of the interpolation string 316 can be fixed by burning or blowing at least one polysilicon fuse based on the received trim code.

The output 311 of the trim circuit 310 is coupled to a non-inverting input of the amplifier 318. The system current monitor node 304 is coupled to a bottom of the mux circuit 314. The inverting input of the amplifier 318 is node 320. The output of the amplifier 318 is coupled to a control node 322 of the output transistor 308, e.g., a FET. The amplifier 318 is configured in a closed feedback loop to control the output monitor current IOUTP in a manner that tends to reduce or minimize a voltage difference across the inputs of the amplifier 318.

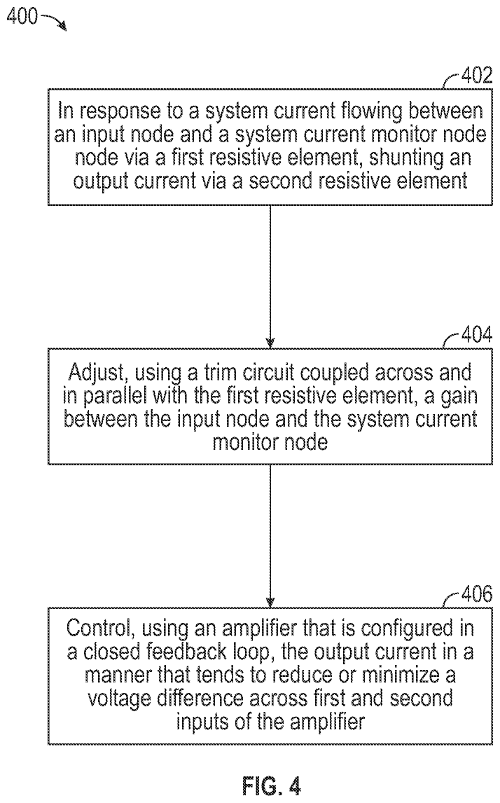

FIG. 4 is a flow chart of an example of a method 400 of sensing or measuring a system current. At block 402, the method 400 in response to a system current flowing between an input node and a system current monitor node via a first resistive element, e.g., resistive element RS in FIGS. 2 and 3, shunting an output current via a second resistive element, e.g., resistive element R1 in FIGS. 2 and 3.

At block 404, the method 400 adjusts, using a trim circuit coupled across and in parallel with the first resistive element, a trim gain between the input node and the system current monitor node. In some examples, adjusting, using the trim circuit coupled across and in parallel with the first resistor, the gain between the input node and the system current monitor node includes receiving a trim code and, in response, modifying a voltage between the input node and the system current monitor node. In some examples, modifying the voltage between the input node and the system current monitor node includes modifying a resistance of a variable resistance. In some examples, modifying the resistance of the variable resistance includes burning or blowing at least one polysilicon fuse based on the received trim code.

In some examples, adjusting, using the trim circuit coupled across and in parallel with the first resistive element, the gain between the input node and the system current monitor node includes using a digital-to-analog converter to modify a resistance of a variable resistance coupled across and in parallel with the first resistive element, such as shown in FIG. 3.

At block 406, the method 400 controls, using an amplifier that is configured in a closed feedback loop, the output current in a manner that tends to reduce or minimize a voltage difference across first and second inputs of the amplifier.

In some examples, the method 400 includes thermally coupling the first resistive element and the second resistive element to keep a temperature of the second resistive element at or near a temperature of the first resistive element when a system current is flowing through and heating the first resistive element.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A system current sensor module for accurately performing at least one of a current sensing or measurement of a system current, the system current sensor module comprising:
an input node, an output node, and a system current monitor node;
an output transistor coupled between the input node and the output node;
a first resistive element coupled between the input node and the system current monitor node;
a second resistive element coupled between the input node and the output transistor; and
an amplifier, including a first amplifier input coupled to the second resistive element, a second amplifier input coupled to an output node of a trim circuit, and an amplifier output coupled to a control node of the output transistor.

2. The system current sensor module of claim 1, wherein the trim circuit is configured to receive a trim code and, in response, modify a voltage between the input node and the system current monitor node.

3. The system current sensor module of claim 2, wherein the trim circuit configured to modify a voltage between the input node and the system current monitor node is configured to:
couple a resistance corresponding to the trim code in parallel with the first resistive element to adjust a gain between a system load current and a output monitor current.

4. The system current sensor module of claim 1, wherein the first resistive element and the second resistive element are thermally coupled to keep a temperature of the second resistive element at or near a temperature of the first resistive element when a system load current is flowing through and heating the first resistive element.

5. The system current sensor module of claim 1, wherein the first resistive element and the second resistive element include the same material.

6. The system current sensor module of claim 1, wherein the trim circuit includes a digital-to-analog converter.

7. The system current sensor module of claim 6, wherein the digital-to-analog converter includes a voltage digital-to-analog converter.

8. The system current sensor module of claim 7, wherein the voltage digital-to-analog converter includes a R-2R digital-to-analog converter.

9. The system current sensor module of claim 1, wherein the first resistive element has a first node and a second node, and wherein the trim circuit is coupled with the first node and the second node.

10. A method of sensing or measuring a system current comprising:
in response to a system current flowing between an input node and a system current monitor node via a first resistive element, shunting an output current via a second resistive element;
adjusting, using a trim circuit coupled across and in parallel with the first resistive element, a gain between the input node and the system current monitor node; and
controlling, using an amplifier that is configured in a closed feedback loop, the output current in a manner that tends to reduce or minimize a voltage difference across first and second inputs of the amplifier.

11. The method of claim 10, comprising:
thermally coupling the first resistive element and the second resistive element to keep a temperature of the second resistive element at or near a temperature of the first resistive element when the system current is flowing through and heating the first resistive element.

12. The method of claim 10, wherein adjusting, using the trim circuit coupled across and in parallel with the first resistive element, the gain between the input node and the system current monitor node includes:
receiving a trim code and, in response, modifying a voltage between the input node and the system current monitor node.

13. The method of claim 12, modifying the voltage between the input node and the system current monitor node includes:
modifying a resistance of a variable resistance.

14. The method of claim 13, wherein modifying the resistance of the variable resistance includes:
burning or blowing at least one polysilicon fuse based on the received trim code.

15. The method of claim 12, wherein adjusting, using the trim circuit coupled across and in parallel with the first resistive element, the gain between the input node and the system current monitor node includes:
using a digital-to-analog converter to modify a resistance of a variable resistance coupled across and in parallel with the first resistive element.

16. A system current sensor module for accurately performing at least one of a current sensing or measurement of a system current, the system current sensor module comprising:
an input node, an output node, and a system current monitor node;
an output transistor coupled between the input node and the output node;
a first resistive element coupled between the input node and the system current monitor node;
a second resistive element coupled between the input node and the output transistor;
means for adjusting a gain between the input node and the system current monitor node; and
means for controlling the output monitor current in a manner that tends to reduce or minimize a voltage difference across first and second inputs of an amplifier.

17. The system current sensor module of claim 16, wherein the means for adjusting a gain is configured to receive a code and, in response, modify a voltage between the input node and the system current monitor node.

18. The system current sensor module of claim 16, wherein the first resistive element has a first node and a second node, and wherein the means for adjusting is coupled with the first node and the second node.

19. The system current sensor module of claim 16, wherein the first resistive element and the second resistive element include the same material.

20. The system current sensor module of claim 16, wherein the first resistive element and the second resistive element are thermally coupled to keep a temperature of the second resistive element at or near a temperature of the first resistive element when a system current is flowing through and heating the first resistive element.
